(19) United States
(12) Patent Application Publication
(10) Pub. No.: US 2022/0141923 A1
(43) Pub. Date: May 5, 2022

(54) A BUS BAR SYSTEM

(71) Applicant: VALEO AUTOMOTIVE AIR CONDITIONING HUBEI CO. LTD., Jingzhou, Hubei (CN)

(72) Inventors: Ziran Tong, Jingzhou, Hubei (CN); Kong Zhang, Jingzhou, Hubei (CN)

(73) Assignee: VALEO AUTOMOTIVE AIR CONDITIONING HUBEI CO. LTD., Jingzhou, Hubei (CN)

(21) Appl. No.: 17/434,267

(22) PCT Filed: Feb. 27, 2020
(86) PCT No.: PCT/CN2020/076938

§ 371 Date: Aug. 26, 2021

(30) Foreign Application Priority Data
Feb. 28, 2019 (CN) 201910149503.8

(51) Int. Cl. H05B 3/06; H05K 1/02; H01R 11/01

(52) U.S. Cl. CPC H05B 3/06; H05K 1/0263; B60H 1/2218; H05K 2201/10272; H01R 11/01

(57) ABSTRACT

A bus-bar system 100 includes at least one bus-bar terminal 10. Each Bus-bar terminal 10 includes a first portion 10a, a second portion 10b and an intermediate portion 10c. The first portion 10a is connected to a heating element 20 of a heating block 22. The second portion 10b is connected to a Printed Circuit Board (PCB) 30 held within a casing 32 and the intermediate portion 10c connects the first portion 10a to the second portion 10b. The first portion 10a and the second portion 10b are offset from each other and the offset is based on desired position and orientation of the Printed Circuit Board (PCB) 30 held inside the casing 32 with respect to the heating elements 20.

The present disclosure relates to a bus-bar system, particularly, the present disclosure relates to bus-bar terminals of a bus-bar system.

Generally, high current handling Printed Circuit Board (PCB) were conventionally configured of copper, however, Printed Circuit Board of such configuration are expensive. Accordingly, bus-bar embedded Printed Circuit Board (PCB) is preferred as such configuration of bus-bar system enables configuring or assembling of different parts on bus-bar terminals of the bus-bar system and the bus-bar terminals distribute power to the different parts. The bus-bar system includes a plurality of bus-bar terminals, wherein one end of each of the bus-bar terminals is connected to a heating element of a heating device such as for example; a heater used in a vehicle and the other end of the bus-bar terminal is connected to the Printed Circuit Board (PCB). The Bus bar terminals are often metallic strips of conductive material such as copper, brass, or aluminum that both ground and conduct electricity. For example, the heating element may be used for cold starting an engine of a vehicle or the heating element is configured downstream of an evaporator of a Heating Ventilation and Air Conditioning unit used in the vehicle for achieving and maintaining comfort conditions inside a vehicle cabin. Also, such configuration of the bus bar embedded PCB results in effective heat dissipation by combining copper inlay.

Generally, such heater elements used in vehicle environment are required to be strategically placed and packaged in a limited space, for example, in case the heating element is for cold starting the engine then the heating element is required to be placed near the engine of the vehicle and in confined space of an engine compartment. In case the heating element is used in Heating Ventilation and Air conditioning system, the heating element is disposed downstream of the evaporator in a confined space inside the Heating Ventilation and Air conditioning housing. As such there are not many options for packaging of the heating element in the available confined space and the position of the heating element is fixed. The conventional bus-bar embedded Printed Circuit Board (PCB) is disposed in a casing for protecting the delicate circuitry configured on the Printed Circuit Board (PCB). As the Bus-bar terminals emanating from the Printed Circuit Board (PCB) are connected to the heating elements, the casing covering and holding the Printed Circuit Board (PCB) is required to be disposed in line or aligned with the heating elements and as such position of casing holding the Printed Circuit Board (PCB) is also fixed. More specifically, with the conventional bus-bar terminals, the position of the casing holding the Printed Circuit Board (PCB) is fixed. However, in some cases considering packaging constrains and customer requirements, the position of the casing holding the Printed circuit board is required to be shifted away from the heating elements.

Accordingly, there is a need for a bus-bar system with bus-bar terminals that permit mounting of a casing holding a Printed Circuit Board (PCB) at a desired position away from the heating elements based on packaging constrains and customer requirements.

An object of the present invention is to provide a bus-bar system with bus-bar terminals that obviates the drawbacks associated conventional bus-bar system and bus-bar terminals.

Another object of the present invention is to provide a bus-bar system that is simple in construction and is in-expensive.

Still another object of the present invention is to provide bus-bar system that facilitates convenient connection between the heating elements and the Printed Circuit Board (PCB).

Another object of the present invention is to provide bus-bar system that facilitates flexibility in placement and packaging of the Printed Circuit Board (PCB) and the casing holding the Printed Circuit Board (PCB).

In the present description, some elements or parameters may be indexed, such as a first element and a second element. In this case, unless stated otherwise, this indexation is only meant to differentiate and name elements which are similar but not identical. No idea of priority should be inferred from such indexation, as these terms may be switched without betraying the invention. Additionally, this indexation does not imply any order in mounting or use of the elements of the invention.

A bus-bar system, hereinafter referred to as “system” is disclosed in accordance with an embodiment of the present disclosure. The system includes at least one bus-bar terminal. Each Bus-bar terminal includes a first portion, a second portion and an intermediate portion. The first portion is connected to a heating element of a heating block. The second portion is connected to a Printed Circuit Board (PCB) held within a casing and the intermediate portion connects the first portion to the second portion. The first portion and the second portion are offset from each other and the offset is based on desired position and orientation of the Printed Circuit Board (PCB) held inside the casing with respect to the heating elements.

In accordance with an embodiment of the invention, the intermediate portion is coplanar with at least one of the first portion and the second portion.

In accordance with another embodiment of the invention, the intermediate portion is offset with respect to at least one of the first portion and the second portion.

Alternatively, the intermediate portion is orthogonal to at least one of the first portion and the second portion.

Otherwise, the intermediate portion is at an angle with respect to at least one of the first portion and the second portion.

In accordance with an embodiment of the invention, the intermediate portion so connects the first portion to the second portion that the first portion and second portion are juxtaposed to each other to facilitate mounting of the Printed Circuit Board (PCB) sideways with respect to but away from the heating elements.

Alternatively, the intermediate portion so connects the first portion to the second portion that the first portion and the second portion are offset to each other to facilitate mounting of the Printed Circuit Board (PCB) at an offset and away from the heating elements.

In accordance with another embodiment, the first portion and the second portion are along different planes that are at an angle with respect to each other to facilitate mounting of the Printed Circuit Board (PCB) away from the heating elements.

In accordance with still another embodiment, the first portion and the second portion are on opposite sides of a reference plane perpendicular to the Printed Circuit Board (PCB).

In accordance with an embodiment of the invention, the intermediate portion is having a curved profile.

Specifically, the intermediate portion is comparatively wider than the first portion and the second portion.

Also is disclosed a heating device for a motor vehicle in accordance with an embodiment of the present invention. The heating device includes a heating block, a Printed Circuit Board and a bus bar system. The heating block includes heating elements. The Printed Circuit Board (PCB) is held inside a casing and is disposed at a desired position with respect to the heating elements. The bus bar system includes least one bus bar terminal, wherein each bus bar terminal includes a first portion, a second portion and an intermediate portion. The first portion is connected to a heating element of the heating block. The second portion is connected to the Printed Circuit Board. The intermediate portion connects the first portion to the second portion. The first portion and the second portion are offset from each other and the offset is based on the desired position of the Printed Circuit Board (PCB) held within the casing with respect to the heating elements.

Other characteristics, details and advantages of the invention can be inferred from the description of the invention hereunder. A more complete appreciation of the invention and many of the attendant advantages thereof will be readily obtained as the same becomes better understood by reference to the following detailed description when considered in connection with the accompanying figures, wherein:

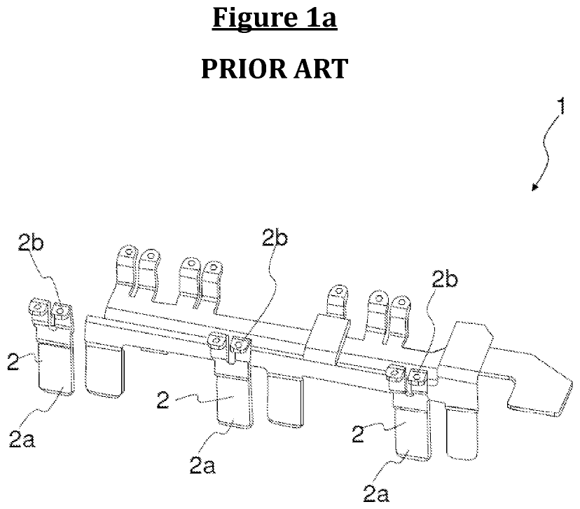

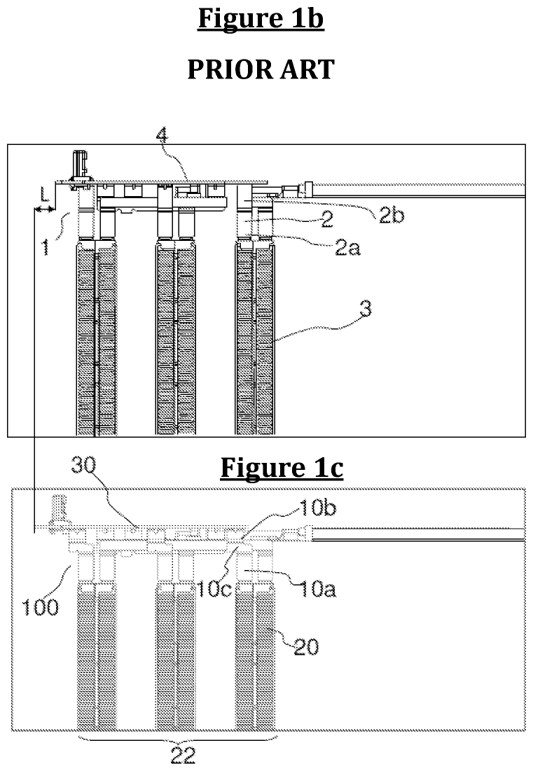

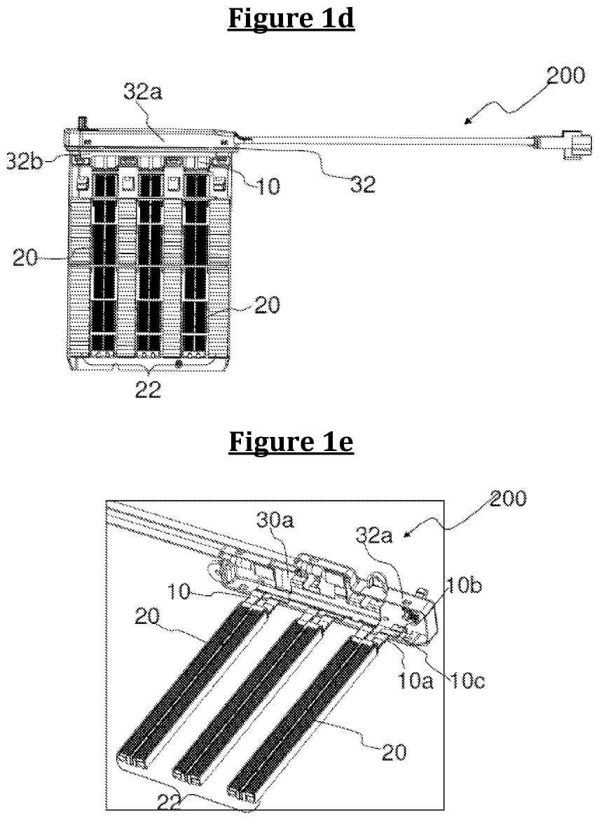

FIG. 1a illustrates an isometric view of a bus-bar system in accordance with the prior art;

FIG. 1b and FIG. 1c illustrate comparison between bus-bar system of the prior art and the bus-bar system of the present invention;

FIG. 1d illustrates a heating device that includes a heating block, a Printed Circuit Board and a bus bar system, wherein the Printed Circuit Board (PCB) is held inside a casing; and

FIG. 1e illustrates the casing holding the Printed Circuit Board (PCB) of the heating device of FIG. 1d;

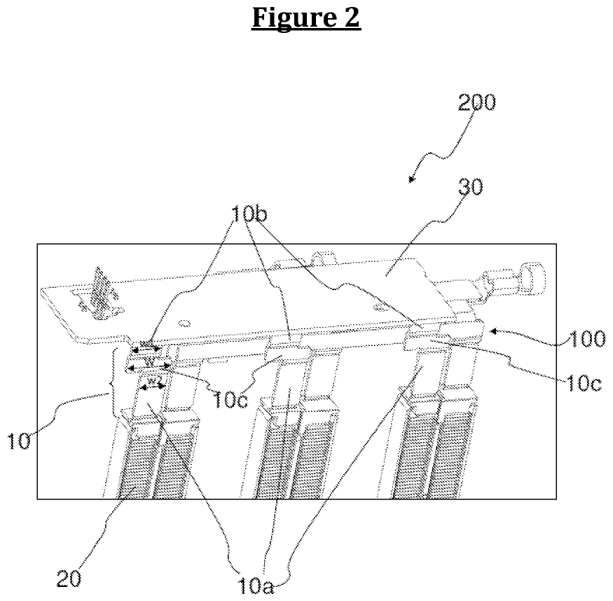

FIG. 2 illustrates a schematic representation depicting the bus-bar system of FIG. 1c, wherein one end of each bus-bar terminal of the bus-bar system is connected to a Printed Circuit Board (PCB) while the other end is connected to a heating element of a heating block; and

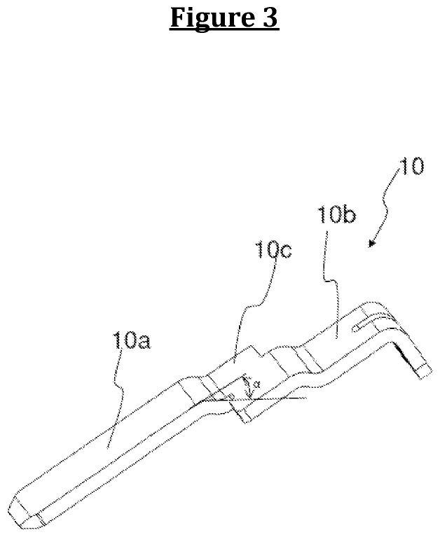

FIG. 3 illustrates an enlarged view depicting the bus-bar terminal depicted in FIG. 2.

It must be noted that the figures disclose the invention in a detailed enough way to be implemented, said figures helping to better define the invention if needs be. The invention should however not be limited to the embodiment disclosed in the description.

A bus-bar system and bus-bar terminal thereof for use in a heating device used in a Heating Ventilation and Air Conditioning (HVAC) system or a cold starting system of a vehicle is disclosed in accordance with an embodiment of the present disclosure. Although, the bus-bar system and bus-bar terminal thereof is explained for use in the Heating ventilation and Air-Conditioning system or cold starting system of vehicles, however, the bus-bar system and bus-bar terminal thereof is applicable for other applications also and is not limited to use in a heating devices or use in vehicle applications only.

FIG. 1a and FIG. 1b illustrates a bus-bar system 1 in accordance with the prior art. The conventional bus-bar system 1 includes at least one bus-bar terminal 2 that is straight, wherein, one end 2a of the at least one bus-bar terminal 2 is connected to corresponding heating element 3 of a heating block while the other end of the bus-bar terminal 2b is connected to a Printed Circuit Board 4. Generally, the heating elements 3 of the heating block are packaged in a confined space and there are not many options for placing the heating elements 3, accordingly, the position of the heating element 3 is fixed. The conventional bus-bar embedded Printed Circuit Board (PCB) 4 is disposed in a casing (not illustrated) for protecting the delicate circuitry configured on the Printed Circuit Board (PCB) 4. Referring to the FIG. 1b, with the conventional bus-bar terminals 2 emanating from the Printed Circuit Board (PCB) 4 and connecting the Printed Circuit Board (PCB) 4 to the heating elements 3, the casing covering and holding the Printed Circuit Board (PCB) 4 is required to be disposed in line or aligned with the heating elements 3 and as such position of casing holding the Printed Circuit Board (PCB) 4 is also fixed. More specifically, with the conventional bus-bar terminals 2, the position of the casing holding the Printed Circuit Board (PCB) 4 is fixed and the position of the casing holding the Printed circuit board cannot be shifted away from the heating elements 3 to comply with the packaging constrains and customer requirements. Such inflexibility in placement and packaging of the Printed Circuit Board (PCB) 4 and the casing holding the Printed Circuit Board (PCB) 4 with respect to the heating elements 3 may causes inappropriate placement and various adjustments in the placement of the Printed Circuit Board (PCB) 4, the casing holding the Printed Circuit Board (PCB) 4 and other elements near thereto.

In accordance with an embodiment of the present invention, the bus bar system 100 is disclosed. The bus bar system 100 includes at least one bus-bar terminal 10. Each Bus-bar terminal 10 includes a first portion 10a, a second portion 10b and an intermediate portion 10c. The first portion 10a is connected to a corresponding heating element 20 of a heating block. The second portion 10b is connected to a Printed Circuit Board (PCB) 30 held within a casing 32 and the intermediate portion 10c connects the first portion 10a to the second portion 10b. The first portion 10a and the second portion 10b are offset from each other and the offset is based on desired position and orientation of the Printed Circuit Board (PCB) 30 held inside the casing 32 with respect to the heating elements 20 Referring to FIG. 1d, the casing 32 is generally having a modular configuration. Particularly, the casing 32 is formed by assembling together top and bottom portions 32a and 32b. The top and bottom portions 32a and 32b can be assembled by using engagement elements such as for example snap fit engagement elements. Such a modular configuration of the casing 32 provides access to the interior of the casing 32 for ease of maintenance and replacement of damaged or worn out elements. The casing 32 receives and holds the Printed circuit board (PCB) 30. Particularly, the top portion 32a of the casing 32 holds the Printed Circuit Board (PCB) 30 of the heating device 200. FIG. 1e illustrates the casing 32 without the bottom portion 32b thereof for depicting the inside of the casing 32.

The configuration and connection of the intermediate portion 10c with respect to the first portion 10a and the second portion 10b of the bus-bar terminal 10 defines the offset between the first portion 10a and the second portion 10b of the bus-bar terminal 10. For example, based on the configuration and connection of the intermediate portion 10c with respect to the first portion 10a and the second portion 10b of the bus-bar terminal 10, the first and second portions 10a and 10b can be in one plane or different planes, accordingly, the Printed circuit board (PCB) connected to the second portions 10b of the bus-bar terminal 10 along with the casing 32 thereof can be disposed at a distance with respect to the heating elements 20 connected to the first portions 10a, to provide flexibility to appropriately place the Printed circuit board (PCB) 30 along with the casing 32 thereof with respect to the heating elements 20 and without interfering with other elements. In accordance with an embodiment of the present invention, the intermediate portion 10c is coplanar with at least one of the first portion 10a and the second portion 10b. Alternatively, the intermediate portion 10c is offset with respect to at least one of the first portion 10a and the second portion 10b. In one embodiment, the intermediate portion 10c so connects the first portion 10a to the second portion 10b that the first portion 10a and the second portion 10b are on opposite sides of a reference plane perpendicular to the Printed Circuit Board (PCB) 30. The intermediate portion 10c can be orthogonal to at least one of the first portion 10a and the second portion 10b. Alternatively, the intermediate portion 10c is at an angle “a” with respect to at least one of the first portion 10a and the second portion 10b .In another embodiment, the intermediate portion 10c so connects the first portion 10a to the second portion 10b that the first portion 10a and the second portion 10b are juxtaposed to each other to facilitate mounting of the Printed Circuit Board (PCB) 30 sideways with respect to but away from the heating elements 20. Referring to the FIG. 2, the intermediate portion 10c is comparatively wider than the first portion 10a and the second portion 10b. More specifically, the intermediate portion 10c is having width “W” that is greater than width “w1” and “w2” of the first portion 10a and the second portion 10b respectively. Such configuration of the intermediate portion 10c, allows the first portion 10a and the second portion 10b to be laterally offset from each other, while still being orthogonally extending in opposite directions from the intermediate portion 10c. Alternatively, the intermediate portion 10c connects the first portion 10a to the second portion 10b in such a way that the first portion 10a and the second portion 10b are offset to each other to facilitate mounting of the Printed Circuit Board (PCB) 30 at an offset and away from the heating elements 20. In one embodiment, the intermediate portion 10c so connects the first portion 10a to the second portion 10b that the first portion 10a and the second portion 10b are along different planes that are at an angle with respect to each other to facilitate mounting of the Printed Circuit Board (PCB) 30 away from the heating elements 20. In accordance with an embodiment of the invention, the intermediate portion 10c is having a curved profile. The intermediate portion 10c is comparatively wider than the first portion 10a and the second portion 10b. The bus-bar terminal 10 is of conductive metal and is configured by stamping or forming operation. FIG. 1b and FIG. 1c illustrate comparison between bus-bar system of the prior art and the bus-bar system of the present invention. Particularly, with the use of the bus-bar terminal 10 of the present invention for connecting the Printed Circuit Board (PCB) to the heating elements, the Printed Circuit Board (PCB) 30 along with the casing 32 holding the Printed Circuit Board (PCB) 30 is shifted sideways with respect to the heating elements by a distance “L” as compared to when conventional bus-bar terminal 2 connects the Printed Circuit Board (PCB) to the heating elements. However, the present invention is not limited to any particular shape, number, configuration of the bus-bar terminal 10 or material or process of manufacturing the bus-bar terminal or any particular configuration of the intermediate portion 10c connecting the first portion 10a and the second portion 10b of the bus-bar terminal 10 as far as such configuration enables the first portion 10a and the second portion 10b to be spaced with respect to each other to facilitate mounting of the Printed Circuit Board (PCB) 30 away from the heating elements 20.

In accordance with an embodiment of the present invention, a heating device 200 for a motor vehicle is disclosed and illustrated in FIG. 1d, FIG. 1e and FIG. 2. The heating device 200 includes a heating block 22, a Printed Circuit Board 30 and a bus bar system 100. The heating block 22 includes heating elements 20. The Printed Circuit Board (PCB) 30 is held inside a casing 32 and is disposed at a desired position with respect to the heating elements 20. The bus bar system 100 includes least one bus bar terminal 10, wherein each bus bar terminal 10 includes a first portion 10a, a second portion 10b and an intermediate portion 10c as illustrated in FIG. 3. The first portion 10a is connected to a corresponding heating element 20 of the heating block 22. The second portion 10b is connected to the Printed Circuit Board 30. The intermediate portion 10c connects the first portion 10a to the second portion 10b. The first portion 10a and the second portion 10b are offset from each other and the offset is based on the desired position of the Printed Circuit Board (PCB) 30 held within the casing 32 with respect to the heating elements 20.

Several modifications and improvement might be applied by the person skilled in the art to the bus-baa system 100 as defined above, as long as it comprises at least one bus-bar terminal. Each Bus-bar terminal includes a first portion, a second portion and an intermediate portion. The first portion is connected to a heating element of a heating block. The second portion is connected to a Printed Circuit Board (PCB) held within a casing and the intermediate portion connects the first portion to the second portion. The first portion and the second portion are offset from each other and the offset is based on desired position and orientation of the Printed Circuit Board (PCB) held inside the casing with respect to the heating elements.

In any case, the invention cannot and should not be limited to the embodiments specifically described in this document, as other embodiments might exist. The invention shall spread to equivalent means and arty technically operating combination of means.

1. A bus bar system comprising:
at least one bus bar terminal comprising:
a first portion adapted to be connected to a heating element of a heating block;
a second portion adapted to be connected to a Printed Circuit Board (PCB) held within a casing; and
an intermediate portion connecting the first portion to the second portion,
wherein the first portion and the second portion are offset from each other and the offset is based on desired position and orientation of the Printed Circuit Board (PCB) held inside the casing with respect to the heating elements.

2. The bus bar system as claimed in claim 1, wherein the intermediate portion is coplanar with at least one of the first portion and the second portion.

3. The bus bar system as claimed in claim 1, wherein the intermediate portion is offset with respect to at least one of the first portion and the second portion.

4. The bus bar system as claimed in claim 1, wherein the intermediate portion is orthogonal to at least one of the first portion and the second portion.

5. The bus bar system as claimed in claim 1, wherein the intermediate portion is at an angle with respect to at least one of the first portion and the second portion.

6. The bus bar system as claimed in claim 1, wherein the intermediate portion is adapted to so connect the first portion to the second portion that the first portion and second portion are juxtaposed to each other to facilitate mounting of the Printed Circuit Board (PCB) sideways with respect to but away from the heating elements.

7. The bus bar system as claimed in claim 1, wherein the intermediate portion is adapted to so connect the first portion to the second portion that the first portion and the second portion are offset to each other to facilitate mounting of the Printed Circuit Board (PCB) at an offset and away from the heating elements.

8. The bus bar system as claimed in claim 1, wherein the first portion and the second portion are along different planes that are at an angle with respect to each other to facilitate mounting of the Printed Circuit Board (PCB) away from the heating elements.

9. The bus bar systems as claimed in claim 1, wherein the first portion and the second portion are on opposite sides of a reference plane perpendicular to the Printed Circuit Board (PCB) [[(30)

10. The bus bar system as claimed in claim 1, wherein the intermediate portion is having a curved profile.

11. The bus bar system as claimed in claim 1, wherein the intermediate portion is comparatively wider than the first portion and the second portion.

12. A heating device for a motor vehicle comprising:
a heating block comprising heating elements;
a Printed Circuit Board (PCB) held inside a casing and is adapted to be disposed at a desired position with respect to the heating elements;
a bus bar system comprises least one bus bar terminal, each bus bar terminal comprising:
a first portion adapted to be connected to a heating element of the heating block;
a second portion adapted to be connected to the Printed Circuit Board (PCB); and
an intermediate portion connecting the first portion to the second portion,
wherein the first portion and the second portion are offset from each other and the offset is based on the desired position of the Printed Circuit Board (PCB) held within the casing with respect to the heating elements.
